(19) United States
(12) Patent Application Publication
(10) Pub. No.: US 2006/0231871 A1
(43) Pub. Date: Oct. 19, 2006

(54) Semiconductor device

(75) Inventors: Hirotaka Amasuga, Tokyo (JP); Toshihiko Shiga, Tokyo (JP); Tetsuo Kunii, Tokyo (JP); Tomoki Oku, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/374,141

(22) Filed: Mar. 14, 2006

(30) Foreign Application Priority Data
Apr. 18, 2005 (JP) 2005-119495

(51) Int. Cl. H01L 29/80; H01L 29/76; H01L 31/112; H01L 29/94; H01L 31/00

(52) U.S. Cl. 257/279; 257/289

(57) ABSTRACT

A gate electrode serving as a Schottky electrode includes a TaNx layer and an Au layer. The TaNx layer serves as a barrier metal for preventing atoms from diffusing from the Au layer into a substrate. TaNx does not contain Si, and therefore has a higher humidity resistance than WSiN containing Si. Accordingly, the gate electrode has a higher humidity resistance than a conventional gate electrode including a WSiN layer. Setting a nitrogen content at less than 0.8 can prevent significant degradation in Schottky characteristics as compared to the conventional gate electrode. Setting the nitrogen content at 0.5 or less, Schottky characteristics can be improved more than in the conventional gate electrode.

### BACKGROUND OF THE INVENTION

1. Field of the Invention

The present invention relates to a semiconductor device, and more particularly, to a semiconductor device with an electrode formed on a substrate which includes a compound semiconductor layer mainly made of GaAs.

2. Description of the Background Art

With a growing demand for high frequency communication in recent years, advances in semiconductor devices using a substrate including a compound semiconductor layer mainly made of GaAs (hereinafter referred to as a “GaAs layer”) are being made. Particularly, higher power is required of an amplifier for use in an oscillator for high frequency communication, however, a higher power amplifier easily causes a temperature rise inside a semiconductor device. Electrodes are generally heat-sensitive, and for example, the temperature rise in a semiconductor device easily affects a junction surface between an electrode and a semiconductor layer.

Particularly in a Schottky electrode (e.g., a gate electrode of a high power FET) which is in Schottky contact with a GaAs layer, a slight change in characteristics of a junction surface greatly affects the Schottky characteristics. The Schottky electrode is thus easily affected by the temperature rise in the semiconductor device. Accordingly, the Schottky electrode tends to be made of a high-melting metal such as W, WSi or WSiN. WSiN, in particular, is widely used for making the Schottky electrode because of its good barrier characteristics between Au, which is a common material of metal interconnect lines, and semiconductor, and because of its excellent Schottky characteristics.

A semiconductor device with a Schottky electrode formed on a substrate including a GaAs layer is disclosed, for example, in Japanese Patent Application Laid-Open Nos. 58-188157 (1983), 60-81859 (1985) and 61-117868 (1986).

However, a conventional semiconductor device with a Schottky electrode made of WSiN has a low humidity resistance since W and Si contained in WSiN are easily oxidized, expanded and dissolved by water.

### SUMMARY OF THE INVENTION

An object of the present invention is to provide a semiconductor device with an electrode having a high humidity resistance. Particularly, it is an object of the invention to provide a semiconductor device capable of improving the humidity resistance of a Schottky electrode without significantly degrading Schottky characteristics or with improvements in Schottky characteristics.

According to the present invention, the semiconductor device includes a substrate including a compound semiconductor layer mainly made of GaAs, and an electrode formed on the compound semiconductor layer. The electrode includes a TaNx layer being in contact with the compound semiconductor layer and having a nitrogen content x of less than 0.8.

The electrode and the whole semiconductor device are improved in humidity resistance.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view illustrating the structure of a semiconductor device according to a first preferred embodiment of the present invention;

FIGS. 2 and 3 are sectional views illustrating the structure of a conventional gate electrode;

FIG. 4 is a sectional view illustrating the structure of a semiconductor device according to a second preferred embodiment of the invention;

FIG. 5 is a sectional view illustrating the structure of a semiconductor device according to a third preferred embodiment of the invention; and

FIG. 6 is a sectional view illustrating the structure of a semiconductor device according to a modification of the first preferred embodiment of the invention.

### DESCRIPTION OF THE PREFERRED EMBODIMENTS

### First Preferred Embodiment

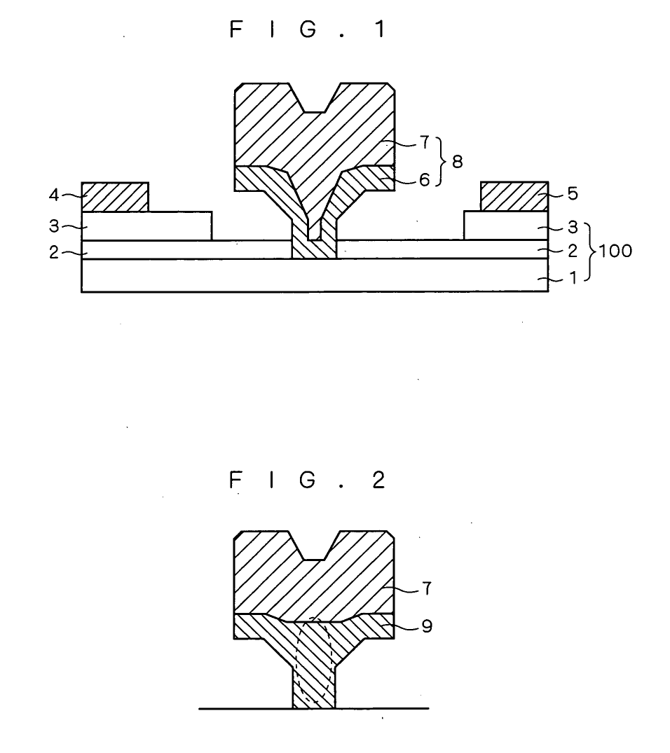

FIG. 1 is a sectional view illustrating the structure of a semiconductor device (high-power FET) according to a first preferred embodiment of the present invention. High-power FETs are classified into MESFET, HFET, HEMT, and the like by the channel structure. The present invention is applicable to any of these structures. Referring to FIG. 1, a substrate 100 includes an AlGaAs layer 1, a GaAs layer 2 and an n⁺-GaAs layer 3 stacked by heterojunction. The substrate 100 may be a GaAs substrate or a stack of an Si substrate (not shown) and a GaAs-based compound semiconductor layer grown on the Si substrate by epitaxial growth or the like. In other words, the substrate 100 should only include a compound semiconductor layer mainly made of GaAs. The GaAs layer 2 is formed on the AlGaAs layer 1. The n⁺-GaAs layer 3 serving as a source/drain region is formed on the GaAs layer 2. A source electrode 4 and a drain electrode 5 are formed on the n⁺-GaAs layer 3.

A T-shaped gate electrode 8 serving as a Schottky electrode is formed on the substrate 100. The gate electrode 8 includes a TaNx layer 6 (x will be described later) and an Au layer 7. The TaNx layer 6 is in contact with the AlGaAs layer 1 and GaAs layer 2. The Au layer 7 is formed on the TaNx layer 6. The TaNx layer 6 serves as a barrier metal for preventing Au atoms contained in the Au layer 7 from diffusing into the substrate 100 and reacting therein.

The Au layer 7 is provided to reduce the total resistance of the gate electrode 8. More specifically, forming the Au layer 7 having a lower resistance than the high-resistive TaNx layer 6 on the TaNx layer 6 can reduce the total resistance of the gate electrode 8. An Al layer, a Cu layer, an Ag layer or the like may be formed instead of the Au layer 7. Au has a resistance of 2.2×10⁻⁶ Ω·cm, Al: 2.8×10⁻⁶ Ω·cm; Cu: 1.7×10⁻⁶ Ω·cm; and Ag: 1.6×10⁻⁶ Ω·cm, all of which are sufficiently lower than the resistance of TaNx (which will be described later). WSiN has a resistance of 100 to 200⁻⁶ Ω·cm.

To reduce the total resistance of the gate electrode 8, it is preferable to form the TaNx layer 6 thin and the Au layer 7 thick. For instance, the TaNx layer 6 is preferably formed 100 nm thick or less, and the Au layer 7 is preferably formed 600 nm thick or more. Since TaNx provides better barrier characteristics between the Au layer 7 and substrate 100 than WSiN, the TaNx layer 6 can be formed thinner than in the case of forming a WSiN layer. As a result, the gate electrode 8 has a lower resistance than a conventional gate electrode including a WSiN layer. A WSiN layer in the conventional gate electrode is formed about 200 nm thick.

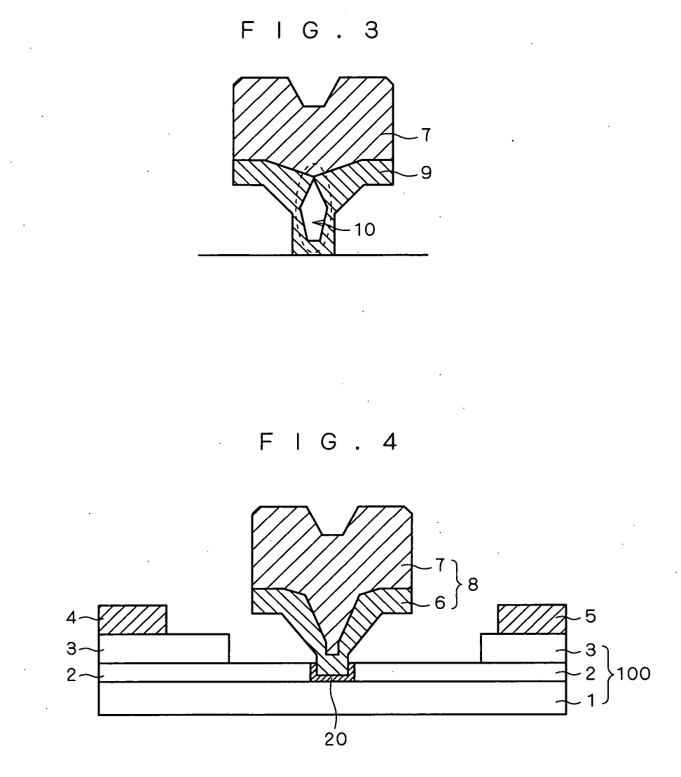

FIGS. 2 and 3 are sectional views illustrating the structure of the conventional gate electrode. A WSiN layer 9 is about 200 nm thick. Accordingly, when the gate electrode has a gate length of 300 nm or less, a depression in the middle portion of the WSiN layer 9 that should be generated resulting from the T-shape of the gate electrode as indicated by dotted lines in FIG. 2 is filled with the WSiN layer 9 itself. As a result, the WSiN layer 9 increases in thickness in that portion, so that the gate electrode increases in resistance. Alternatively, as shown in FIG. 3, a cavity 10 resulting from overhang is created in the middle portion of the WSiN layer 9, which similarly increases the resistance of the gate electrode. In contrast, the problems shown in FIGS. 2 and 3 do not arise in the gate electrode 8 according to the present embodiment even when the gate electrode 8 has a gate length of 300 nm or less because the TaNx layer 6 can be formed 100 nm thick or less.

Next, a suitable nitrogen content (atom ratio) x of the TaNx layer 6 is discussed. TaNx increases in resistance with increasing nitrogen content x. The increase in resistance of the TaNx layer 6 causes the total resistance of the gate electrode 8 to increase, which in turn degrades the gain in high-frequency characteristics. Accordingly, an upper limit of the nitrogen content x needs to be set within a range that degradation in gain is acceptable.

A plurality of TaNx layers 6 each having a different nitrogen content x were prepared, and the resistance of each of the TaNx layers 6 was measured, the results of which are shown in Table 1.

TABLE 1

x

| | 0.1 | 0.5 | 0.8 | 1.0 |
|---|---|---|---|---|
| resistance (×10⁻⁶ Ω · cm) | 150 | 180 | 1000 | 5000 |

When the nitrogen content x is 0.8, the TaNx layer 6 has a resistance of 1000×10⁻⁶ Ω·cm. When the TaNx layer 6 is applied to the gate electrode 8, the total resistance of the gate electrode 8 is reduced by the Au layer 7 formed on the TaNx layer 6. Accordingly, in light of resistance, it can be said that a suitable range of the nitrogen content x is less than 0.8 (0<x<0.8). Here, the nitrogen content x of the TaNx layer 6 may vary within about ±0.1 due to process variations. Therefore, the nitrogen content x is preferably set at less than 0.7 (x<0.7) so as to fall within the suitable range even when it varies to increase.

Ta has a resistance of 150×10⁻⁶ Ω·cm, which is equal to the resistance of the TaNx layer 6 when the nitrogen content x is 0.1. Accordingly, in light of resistance, a Ta layer may be used instead of the TaNx layer 6. However, a Ta layer is polycrystalline while the TaNx layer 6 is amorphous. The Ta layer therefore provides worse barrier characteristics between the Au layer 7 and substrate 100 than the NaTx layer 6. Since the TaNx layer 6 serves as a barrier metal in the gate electrode 8 according to the present embodiment, it is not advantageous to adopt a Ta layer instead of the TaNx layer 6.

Experiments conducted by the inventors of the present invention have revealed that a height Φb of a Schottky barrier between the Schottky electrode and compound semiconductor layer decreases with increasing nitrogen content x when employing compound semiconductor such as GaAs or AlGaAs having a high interface state concentration. Accordingly, an upper limit of the nitrogen content x needs to be set within a range that the decrease in Φb is acceptable. A Schottky diode structure was prepared using a plurality of TaNx layers 6 each having a different nitrogen content x, and the height Φb was evaluated for each of the TaNx layers 6, the results of which are shown in Table 2.

TABLE 2

x

| | 0.1 | 0.5 | 0.8 | 1.0 |
|---|---|---|---|---|
| Φb (eV) | 0.68 | 0.58 | 0.49 | 0.45 |

When the nitrogen content x is 0.8, the height Φb of the TaNx layer 6 is 0.49 eV, which is judged to fall within an acceptable range. Accordingly, in light of height Φb, it can also be said that a suitable range of the nitrogen content x is less than 0.8. As described above, the nitrogen content x is preferably set at less than 0.7 (x<0.7) considering process variations.

The height Φb of WSiN is 0.57 eV. When the nitrogen content x is set at 0.5, the height Φb of the TaNx layer 6 (=0.58 eV) is higher than that of a WSiN layer. Accordingly, in light of increase in height Φb more than in the conventional gate electrode including a WSiN layer, a suitable range of the nitrogen content x is 0.5 or less (0<x≦0.5). Considering process variations, the nitrogen content x is preferably set at 0.4 or less (x≦0.4). When the nitrogen content x is set at 0.5, the TaNx layer 6 has a resistance of 180×10⁻⁶ Ω·cm (see Table 1), which is one-fifth or less of the resistance when the nitrogen content x is set at 0.8, and sufficiently small.

In the semiconductor device according to the first preferred embodiment, the gate electrode 8 serving as a Schottky electrode includes the TaNx layer 6. Since Ta making up TaNx has no corrosion point in a pH-potential diagram (Pourvaix diagram), TaNx has a higher humidity resistance than WSiN containing W and Si which are easy to corrode. Therefore, the gate electrode 8 according to the present embodiment has a higher humidity resistance than the conventional gate electrode including a WSiN layer. Although the above description has been made referring to the Schottky electrode by way of example, an Ohmic electrode (e.g., an emitter electrode of HBT) which is in Ohmic contact with the substrate 100 produces the effect of improving the humidity resistance by providing the TaNx layer 6.

Setting the nitrogen content x at less than 0.8 (less than 0.7 considering process variations) can prevent significant degradation in Schottky characteristics as compared to the conventional gate electrode. Alternatively, setting the nitrogen content x at 0.5 or less (0.4 or less considering process variations) can achieve improved Schottky characteristics as compared to the conventional gate electrode.

### Second Preferred Embodiment

FIG. 4 is a sectional view illustrating the structure of a semiconductor device according to a second preferred embodiment of the present invention. A Ti film 20 is additionally formed on the interface between the gate electrode 8 and substrate 100 in the semiconductor device according to the first preferred embodiment shown in FIG. 1. More specifically, the substrate 100 has a recess with a bottom surface defined by the AlGaAs layer 1 and a side surface defined by the GaAs layer 2. The Ti film 20 is brought into contact with the bottom and side surfaces of the recess. In the present embodiment, the gate electrode 8 is formed on the Ti film 20.

A conventional semiconductor device with a gate electrode including a WSiN layer formed on a GaAs substrate causes reverse-biased voltage-current characteristics between gate and drain electrodes to vary with time along with a change in charging status of Schottky interface state. That is, a current which flows when a constant bias voltage is applied drifts with time (which will be hereinafter called “time variation in breakdown voltage”).

In contrast, experiments conducted by the inventors of the present invention have revealed that the time variation in breakdown voltage can be suppressed by forming the Ti film 20 on the interface between the gate electrode 8 and substrate 100. This is considered because highly reactive Ti reacts with GaAs contained in the substrate 100 to produce the effect of suppressing the time variation in breakdown voltage. The experiments conducted by the inventors of the present invention have confirmed that the Ti film 20 is preferably formed thin, and good characteristics are obtained when the film thickness falls within 2 to 5 nm.

As described above, the semiconductor device according to the second preferred embodiment is capable of achieving a highly stable transistor operation because the Ti film 20 interposed between the gate electrode 8 and substrate 100 suppresses the time variation in breakdown voltage. Forming a Ta film instead of the Ti film 20 may produce a similar effect.

### Third Preferred Embodiment

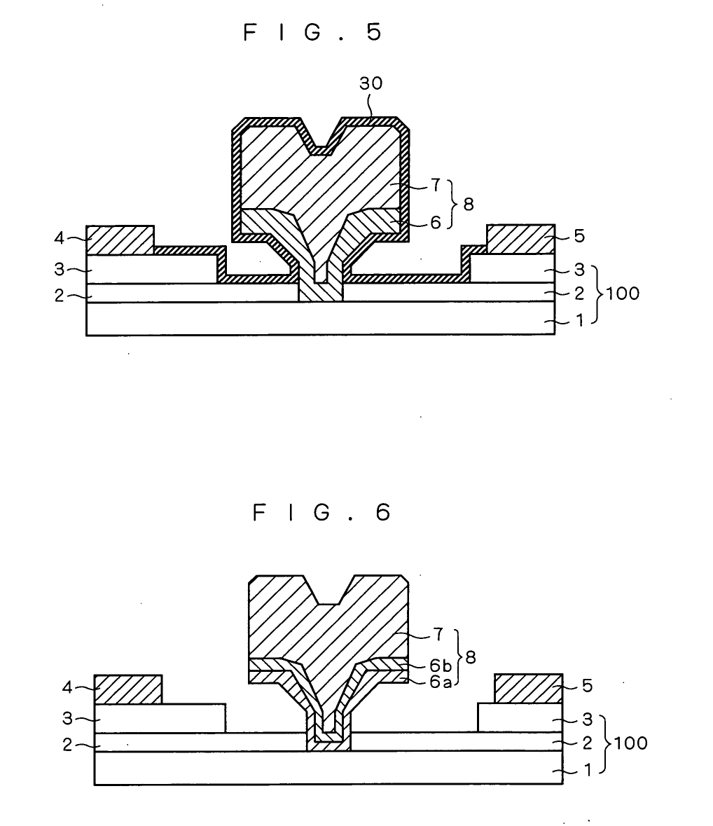

FIG. 5 is a sectional view illustrating the structure of a semiconductor device according to a third preferred embodiment of the present invention. A silicon nitride film 30 is additionally formed to cover an exposed surface of the gate electrode 8 and an exposed surface of the substrate 100 in the semiconductor device according to the first preferred embodiment shown in FIG. 1. The silicon nitride film 30 is formed by a catalytic CVD method (Cat-CVD), and is highly resistant to humidity. Forming the silicon nitride film 30 by Cat-CVD reduces damage to the substrate 100. As a result, a dense insulation film can be formed, which in turn achieves more improved humidity resistance.

As described, in the semiconductor device according to the third preferred embodiment, the exposed surface of the gate electrode 8 and that of the substrate 100 are covered by the silicon nitride film 30 formed by Cat-CVD having a high humidity resistance. Along with the humidity resistance of the TaNx layer 6, the semiconductor device has more improved humidity resistance.

In the case where the gate electrode 8 does not include the Au layer 7, the silicon nitride film 30 is not required to cover the exposed surface of the gate electrode 8. In contrast, as shown in FIG. 5, in the case where the gate electrode 8 includes a low-resistive metal layer (Au layer 7 in the example of FIG. 5), GaAs may corrode due to the battery effect between Au, TaN and the compound semiconductor layer. In this case, it is therefore effective to form the silicon nitride film 30 to cover the exposed surface of the gate electrode 8, as shown in FIG. 5.

Modification

FIG. 6 is a sectional view illustrating the structure of a semiconductor device according to a modification of the first preferred embodiment. The TaNx layer 6 shown in FIG. 1 is divided into a first TaNx layer 6a and a second TaNx layer 6b. The first TaNx layer 6a is in contact with the substrate 100, and the second TaNx layer 6b is formed on the first TaNx layer 6a. The first TaNx layer 6a has a nitrogen content x satisfying 0<x<0.2, while the second TaNx layer 6b has a nitrogen content x satisfying 0.4<x<0.8. As an example, the first TaNx layer 6a has a nitrogen content x of 0.1, and the second TaNx layer 6b has a nitrogen content x of 0.5.

Setting the first TaNx layer 6a in contact with the substrate 100 to have a relatively low nitrogen content x ensures high Φb, which achieves improved Schottky characteristics. Forming the second TaNx layer 6b having a relatively high nitrogen content x improves barrier characteristics, which in turn achieves improved reliability.

Although the present modification is based on the first preferred embodiment, this modification is also applicable to the second and third preferred embodiments.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a substrate including a compound semiconductor layer mainly made of GaAs; and
an electrode formed on said compound semiconductor layer, wherein
said electrode includes a TaNx layer being in contact with said compound semiconductor layer and having a nitrogen content x of less than 0.8.

2. The semiconductor device according to claim 1, wherein
said electrode is in Ohmic contact with said compound semiconductor layer.

3. The semiconductor device according to claim 1, wherein
said electrode is in Schottky contact with said compound semiconductor layer.

4. The semiconductor device according to claim 3, wherein
said TaNx layer has a nitrogen content x of 0.5 or less.

5. The semiconductor device according to claim 3, wherein
said TaNx layer includes:
a first TaNx layer being in contact with said compound semiconductor layer with the nitrogen content x set at a first value; and
a second TaNx layer formed on said first TaNx layer with the nitrogen content x set at a second value higher than said first value.

6. The semiconductor device according to claim 3, further comprising
one of a Ti film and a Ta film formed on an interface between said electrode and said compound semiconductor layer.

7. The semiconductor device according to claim 1, wherein
said electrode further includes a metal layer formed on said TaNx layer having a lower resistance than said TaNx layer.

8. The semiconductor device according to claim 7, further comprising
a silicon nitride film formed by a catalytic CVD method to cover an exposed surface of said electrode.

9. The semiconductor device according to claim 1, further comprising
a silicon nitride film formed by a catalytic CVD method to cover an exposed surface of said compound semiconductor layer.
